(19) United States
(12) Patent Application Publication
(10) Pub. No.: US 2020/0213552 A1
(43) Pub. Date: Jul. 2, 2020

(54) SOLID-STATE IMAGING ELEMENT

(71) Applicant: SHARP KABUSHIKI KAISHA, Sakai City (JP)

(72) Inventors: NOBUYUKI ASHIDA, Sakai City (JP); KUNIHIKO IIZUKA, Sakai City (JP); SHIGENARI TAGUCHI, Sakai City (JP); MASAHIRO SHIOTA, Sakai City (JP)

(21) Appl. No.: 16/725,769

(22) Filed: Dec. 23, 2019

Related U.S. Application Data
(60) Provisional application No. 62/784,849, filed on Dec. 26, 2018.

(51) Int. Cl. H04N 5/3745; H01L 27/146; H04N 5/357

(52) U.S. Cl. CPC H04N 5/37455; H04N 5/357; H01L 27/14612; H01L 27/14643

(57) ABSTRACT

[Object] To reduce 1/f noise by utilizing the functionality of controlling row selection, with which a typical solid-state imaging element is provided.

[Solution] A solid-state imaging element (1A) includes a pixel array (A) in which a plurality of columns of pixels (P) are arranged, a row selection unit (13) that specifies a readout row of the pixel array (A), and a control device (30) that sweeps information carried by each pixel (P) a plurality of times by controlling the row selection unit (13) and outputs an output value in accordance with results of a plurality of readouts of the information obtained from each pixel (P) by the sweeping.

### TECHNICAL FIELD

An aspect of the present invention relates to a solid-state imaging element including a sensor element that produces electrical signals based on the incident radiation dose.

### BACKGROUND ART

As sensor elements that output electrical signals in accordance with the dose of incident radiation, for example, X-rays, those of a direct conversion type that directly convert X-rays to electrical signals are known. Sensor elements of an indirect conversion type that convert X-rays to light by using a scintillator and then to electrical signals by using a photoelectric conversion element, such as a photodiode, are also known.

A panel for X-ray image capture is configured by providing each pixel with the sensor element mentioned above and arranging the pixels in a two-dimensional matrix manner on a substrate (panel). In such a panel, thin film transistor (TFT) elements are used for control of each pixel. In both the direct conversion type and the indirect conversion type, electrical signals (electric charge) produced in accordance with an X-ray dose are to be stored in a capacitor in each pixel.

The element that transfers the stored electrical signals (electric charge) to an amplifier outside of the panel via a TFT element is referred to as a passive pixel type. The element that amplifies the stored electrical signals (electric charge) by using a TFT element as an amplifying element and transmits the resultant to an outside circuit is referred to as an active pixel type. The active pixel type element is capable of amplifying stored electrical signals (electric charge) within the pixel and therefore may obtain larger signals for the same radiation dose than the passive pixel type element. Therefore, there is an advantage that an appropriate signals are obtained with a low radiation dose.

In such a solid-state imaging element, there is a method of integrating signals as a way to obtain a signal with a high signal-to-noise (S/N) ratio. Integrating and averaging signals enables reduction of random noise, such as thermal noise. However, for the 1/f noise, there is a correlation over time. That is, even if the integration time is increased, the signal and the noise equally increase. As a result, even if signals are integrated and averaged, the S/N ratio does not improve. Accordingly, the effect of 1/f noise on product operations are very large.

As used herein, the 1/f noise refers to noise whose output is inversely proportional to a frequency f and is noise that is dominant mainly in a low frequency range. The 1/f noise is an offset that occurs randomly at any time regardless of a timing, such as a reset period or a pixel output period.

In order to reduce the effect of 1/f noise mentioned above to any low level, in an image sensor disclosed in, for example, PTL 1, a transistor is configured to cycle between at least two bias states during a pixel readout phase. As a result, the correlation over time of the 1/f noise of the readout signals decreases. Therefore, the 1/f noise may be reduced by oversampling and averaging the signals where the correlation has decreased.

### CITATION LIST

### Patent Literature

PTL 1: Japanese Unexamined Patent Application Publication No. 2011-234366

### SUMMARY OF INVENTION

### Technical Problem

An aspect of the present invention is to provide a solid-state imaging element that may reduce 1/f noise by utilizing functionality of controlling row selection, with which a typical solid-state imaging element is provided.

### Solution to Problem

(1) One embodiment of the present invention is a solid-state imaging element including a pixel array in which a plurality of columns of pixels are arranged, a row selection unit that specifies a readout row of the pixel array, and a control unit that sweeps information carried by each pixel a plurality of times by controlling the row selection unit and outputs an output value in accordance with results of a plurality of readouts of the information from each pixel obtained by the sweeping.

(2) Additionally, an embodiment of the present invention is a solid-state imaging element in which, in addition to the configuration in (1) mentioned above, the control unit outputs an average value of the results of the readouts obtained by the sweeping performed the plurality of times.

(3) Additionally, an embodiment of the present invention is a solid-state imaging element in which, in addition to the configuration in (2) mentioned above, the control unit calculates the average value after correcting an electric charge leakage that has occurred during the sweeping performed the plurality of times.

(4) Additionally, an embodiment of the present invention is a solid-state imaging element in which, in addition to the configuration in (3) mentioned above, the control unit performs the correcting in accordance with a leakage amount measured in advance by using the solid-state imaging element.

(5) Additionally, an embodiment of the present invention is a solid-state imaging element in which, in addition to the configuration in (1) to (4) mentioned above, when the pixel becomes a non-readout state, a source potential of a transistor included in the pixel changes, and thereby a bias state of the transistor changes.

(6) Additionally, an embodiment of the present invention is a solid-state imaging element in which, in addition to the configuration in (1) to (4) mentioned above, when the pixel becomes a non-readout state, a drain potential of a transistor included in the pixel changes, and thereby a bias state of the transistor changes.

(7) Additionally, an embodiment of the present invention is a solid-state imaging element in which, in addition to the configuration in (1) to (4) mentioned above, when the pixel becomes a non-readout state, the control unit changes a potential of a gate electrode of a transistor included in the pixel.

### Advantageous Effects of Invention

According to an aspect of the present invention, an advantage of reducing 1/f noise by utilizing functionality of controlling row selection, with which a typical solid-state imaging element is provided.

### BRIEF DESCRIPTION OF DRAWINGS

FIG. 1 is a block diagram illustrating a configuration of a solid-state imaging element in a first embodiment of the present invention.

FIG. 2 is a circuit diagram illustrating a configuration of a pixel circuit of the solid-state imaging element.

FIG. 3 is a flowchart illustrating an example of a readout method in the case of detecting X-rays with the solid-state imaging element.

FIG. 4 is a timing chart illustrating a readout method in the case of detection X-rays with the solid-state imaging element.

FIG. 5 is a diagram illustrating reduction in 1/f noise in the solid-state imaging element.

FIG. 6 is a graph illustrating the effect of reduction in 1/f noise in the solid-state imaging element.

FIG. 7 is a circuit diagram illustrating a configuration of a pixel circuit of a solid-state imaging element in a second embodiment of the present invention.

FIG. 8 is a circuit diagram illustrating a configuration of a pixel circuit of a solid-state imaging element in a third embodiment of the present invention.

FIG. 9 is a circuit diagram illustrating a configuration of a pixel circuit of a solid-state imaging element in a fourth embodiment of the present invention.

FIG. 10 illustrates a solid-state imaging element in a fifth embodiment of the present invention and is a sectional view illustrating an example of a configuration of a double-gate thin film transistor.

FIG. 11 is a circuit diagram illustrating a configuration of a pixel circuit of the solid-state imaging element including an Amp transistor using the double-gate thin film transistor.

### DESCRIPTION OF EMBODIMENTS

### First Embodiment

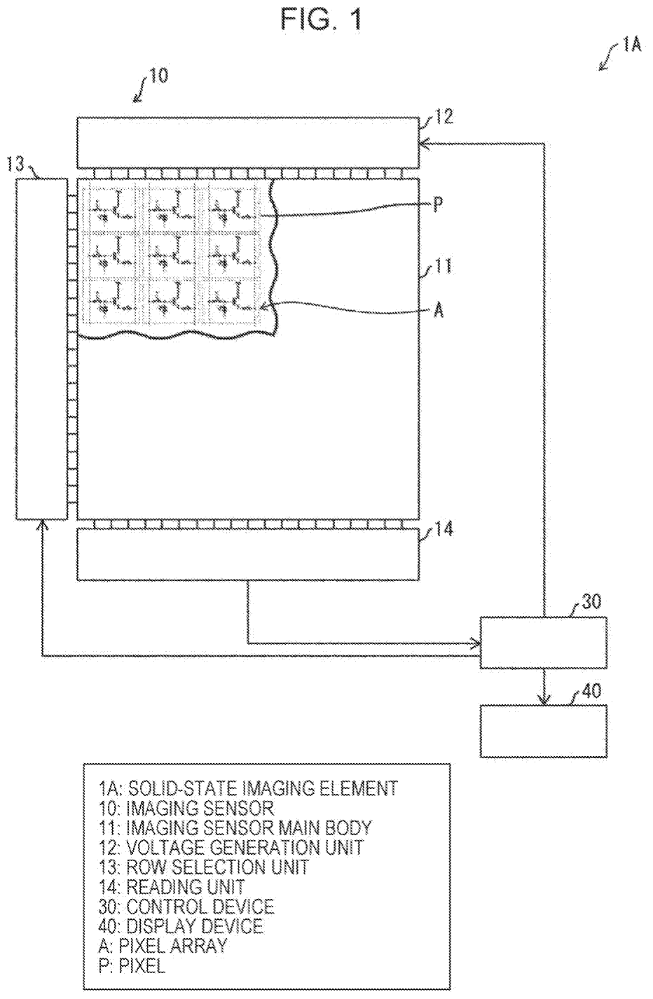

The following is a description of an embodiment of the present invention with reference to FIG. 1 to FIG. 6.

### (Overview of Solid State Imaging Element)

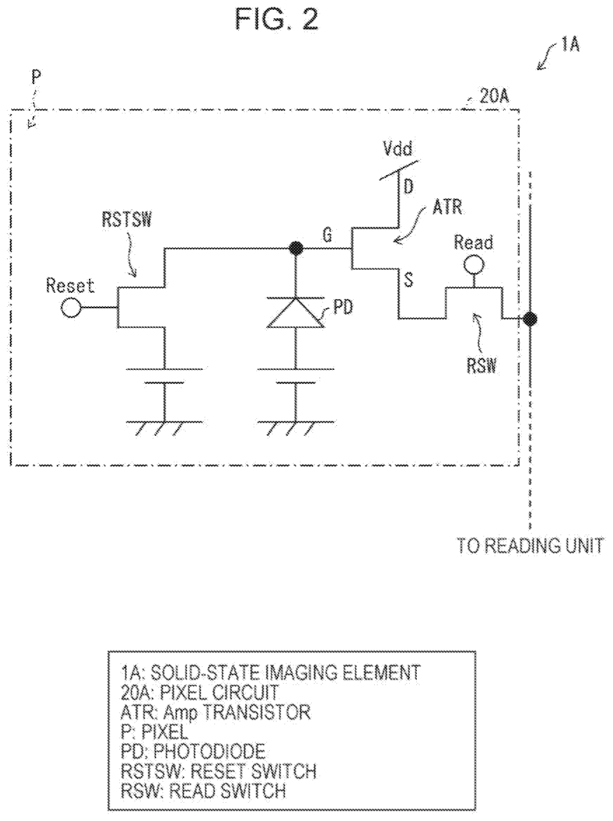

The configuration of a solid-state imaging element 1A in the present embodiment will be described with reference to FIG. 1 and FIG. 2. FIG. 1 is a block diagram illustrating a configuration of a solid-state imaging element 1A. FIG. 2 is a circuit diagram illustrating a configuration of a pixel circuit 20A of the solid-state imaging element 1A. The solid-state imaging element 1A is an active-pixel solid-state imaging element, which allows a stored electrical signals (electric charge) to be amplified within a pixel.

As illustrated in FIG. 1, the solid-state imaging element 1A includes an imaging sensor 10 and a control device (control unit) 30. The imaging sensor 10 includes an imaging sensor main body 11, a voltage generation unit 12, a row selection unit 13, and a reading unit 14. Additionally, coupling a display device 40 to the solid-state imaging element 1A enables construction of an imaging system capable of causing the display device 40 to display an image output by the solid-state imaging element 1A.

The imaging sensor main body 11 is composed of a pixel array made up of a plurality of pixels P arranged in a two-dimensional matrix manner and a scintillator (not illustrated) that covers the front surface of the array. In the present embodiment, the pixel array A is made up of, for example, 512 pixels P in the column direction and 512 pixels P in the row direction. However, the numbers of pixels P in the column direction and pixels P in the row direction in the pixel array A are not limited to this example. The scintillator receives X-rays and has an X-ray-to-light conversion capability of converting the received X-rays to light.

The voltage generation unit 12 generates a voltage to be applied to the pixels P and applies the generated voltage to each column. Additionally, the row selection unit 13 selects a row to which the voltage generated by the voltage generation unit 12 is to be applied. The voltage generation unit 12 applies a voltage to each column and the row selection unit 13 selects a row to which a voltage is to be applied, thereby enabling a voltage to be applied on a per-pixel P basis.

The reading unit 14 reads outputs from the pixels P and transmits the outputs to the control device 30. The control device 30 controls operation timings of the voltage generation unit 12 and the row selection unit 13. Further, the control device 30 outputs information on the pixels P read by the reading unit 14 to the display device 40. The control device 30 may be made of, for example, a circuit.

### (Pixel Circuit)

The circuit configuration of the pixel P will be described with reference to FIG. 2 next. FIG. 2 is a circuit diagram illustrating a configuration of a pixel circuit 20A. As illustrated in FIG. 2, the pixel circuit 20A includes a reset switch RSTSW, a photodiode PD, an Amp transistor ATR, and a read switch RSW.

The reset switch RSTSW is a switch for applying a reset voltage to a gate electrode G of the Amp transistor ATR. As used herein, the reset voltage is a voltage for resetting electric charge generated by the photodiode PD.

The output of the photodiode PD is coupled to the gate electrode G of the Amp transistor ATR. Therefore, when the photodiode receives radiation, such that electric charge (electrical signals) is generated, the voltage of the gate electrode G of the Amp transistor ATR coupled to the photodiode PD changes.

The Amp transistor ATR is a transistor that amplifies electric charge (electrical signals) of the photodiode PD. Specifically, the Amp transistor ATR outputs a voltage change of the gate electrode G as a current change between a drain electrode D and a source electrode S. A power supply voltage Vdd is applied to the drain electrode D, and therefore the electrical signals mentioned above are amplified by the Amp transistor ATR. The Amp transistor ATR may be, for example, a field effect transistor (FET).

The read switch RSW is a switch for outputting a current between the source electrode S and the drain electrode D of the Amp transistor ATR to the outside of the pixel P and is controlled by the reading unit 14 via the control device 30.

In addition, a current output from the pixel P is output to the reading unit 14, is amplified by an analog front end (AFE) (not illustrated) of the reading unit 14, further undergoes analog-to-digital (A/D) conversion, and is output to the control device 30.

(Readout Method for Detection Signals from Photodiode: Reference Example)

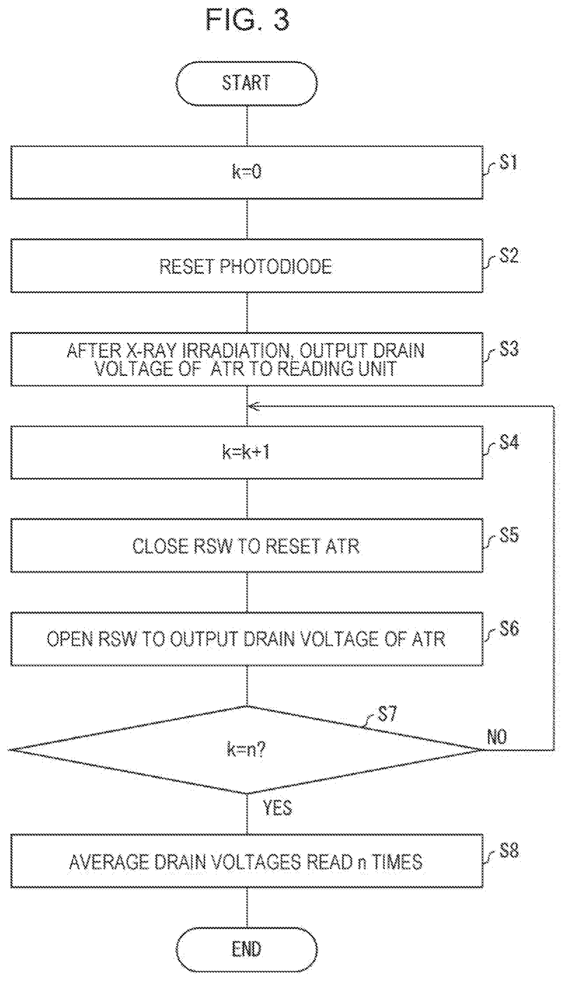

An example of a readout method in the case of detecting X-rays in the pixel circuit 20A will be described with reference to FIG. 3. FIG. 3 is a flowchart illustrating an example of a readout method for a detection signal in the case of detecting X-rays.

Initially, the control device 30 sets a count value k=0 as the initial setting (S1). Subsequently, the control device 30 resets the photodiode PD by using the reset switch RSTSW (S2). After X-ray irradiation occurs in such a situation, the control device 30 opens the read switch RSW to output the drain voltage of the Amp transistor ATR to the reading unit 14 (S3) and performs an operation (k=k+1) of incrementing the count value k by one (S3).

Subsequently, the control device 30 temporarily interrupts the output to the reading unit 14 by closing the read switch RSW, thereby resetting the Amp transistor ATR (S5). Resetting in S5 means switching the Amp transistor ATR from the readout state (ON state) to the non-readout state (OFF state).

Thereafter, the control device 30 again opens the read switch RSW to output the drain voltage of the Amp transistor ATR to the reading unit 14 (S6). Then, after repeating these steps, S4, S5, and S6 n times (S7), the control device 30 averages readout voltages read out n times (S8).

Here, in the Amp transistor ATR, there is no correlation between noise before resetting and noise after resetting. Therefore, noise with no correlation accumulates in the process of S8 mentioned above. Thus, noise may be reduced by increasing the number n of readouts. As a result, the effect of low frequency noise may further be reduced.

### (Method for Reducing 1/f Noise)

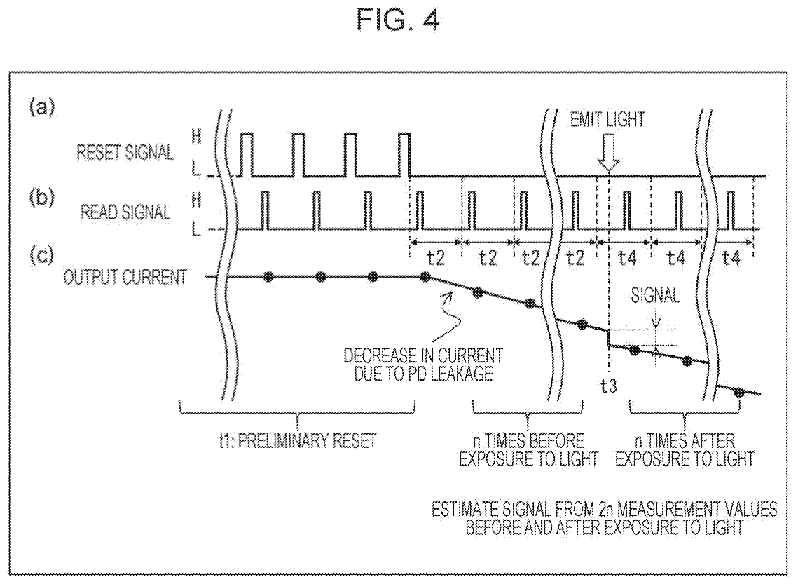

A method for reducing 1/f noise of the Amp transistor ATR by using the reset function of the Amp transistor ATR to change the bias state of the Amp transistor ATR will be described next with reference to FIG. 4. FIG. 4 is a timing chart illustrating another example of the readout method in the case of detecting X-rays in the solid state imaging element 1A. Note that FIG. 4 illustrates operations of the pixels P in the N (N>2) row in the pixel array A of 512 rows.

Here, with regard to noise, 1/f noise of the Amp transistor ATR is greatest. The 1/f noise is unable to be reduced even when the measurement time is increased. In the present embodiment, therefore, the following operations are performed to reduce the 1/f noise of the Amp transistor ATR.

First, as illustrated in (a) of FIG. 4, in a preliminary (prior to X-ray exposure) reset period t1, the control device 30 resets the photodiode PD by using the reset switch RSTSW. In the period t1, the control device 30 sequentially resets the photodiode PD in each of the pixels P from the first row (N=1) to the 512th row (N=512).

Specifically, the control device 30 resets the photodiode PD by causing the reset switch RSTSW to be conductive (setting a reset signal to “H”). In addition, when the control device 30 resets the photodiode PD, as illustrated in (b) of FIG. 4, the control device 30 also sets a read signal to “H” to cause the read switch RSW to be conductive. This is control that takes into account that when the operating state of a transistor changes, it takes time to stabilize the characteristics of the transistor.

If the control device 30 does not set the read signal to “H” in the period t1, the operating states of the Amp transistor ATR and the read switch RSW change at the time at which the readout period begins. The characteristics of the Amp transistor ATR and the reed switch RSW therefore differ between the ith readout time and the (i+1)th readout time. This results in a difference between the ith readout result and the (i+1)th readout result.

In contrast, as illustrated in (b) of FIG. 4, when the read signal is set to “H” in the period t1, in the Amp transistor ATR and the read switch RSW, the fixed operating cycles continue even at the time at which reading begins, resulting in stable characteristics. That is, by setting the read signal to “H” in the period t1, which is sufficiently long for the characteristics to become stable, a difference between the ith reading result and the (i+1)th reading result caused by characteristic fluctuations of the Amp transistor ATR and the read switch RSW may be suppressed.

When resetting of the photodiodes PD from the first row (N=1) to 512th row (N=512) described above is complete, the control device 30 sweeps information carried by each pixel P n times (n being an integer greater than or equal to two) by controlling the row selection unit 13. In (b) of FIG. 4, the period during which one sweep is performed is indicated as t2. A sweep is performed by sequentially causing the read switches RSW from the first row (N=1) to the 512th row (N=512) to be conductive.

In this sweep, when the read switch RSW in the Nth row becomes conductive (the read signal being “H”), the source potential of the Amp transistor ATR at each pixel P in the Nth row also changes, such that the Amp transistor ATR is in the ON state. Thereby, a current (a signal on the Nth row) from each pixel P in the Nth row is output to the AFE (not illustrated) via the reading unit 14. The AFE amplifies the current mentioned above, causes the amplified current to undergo A/D conversion, and outputs the resultant to the control device 30.

In contrast, when the read switch RSW in the Nth row is conductive, the read switches RSW in rows other than the Nth row are open (the read signals are “L”). Thus, the Amp transistor ATR at each pixel P in rows other than the Nth row is in the OFF state.

That is, at each pixel P in the Nth row, in the period t2, the Amp transistor ATR is in the OFF state until the read switch RSW in the Nth row becomes conductive, and, when the read switch RSW in the Nth row becomes conductive, the source potential of the Amp transistor ATR changes, such that the bias state of the Amp transistor ATR changes. Then, when the read switch RSW in the Nth row returns back to a non-conductive state, the source potential of the Amp transistor ATR changes, such that the bias state of the Amp transistor ATR changes.

When the sweep at the pixels P in the first to 512th rows is complete in such a way, the control device 30 performs the second sweep at the pixels P in the first to 512th rows under the same control as described above. Here, in the period t2 during which the first sweep is performed, a period during which the read switch RSW in the Nth row is conductive is sufficiently shorter than a period during which the read switch RSW in the Nth row is non-conductive. Therefore, the Amp transistors ATR at the pixels P in each row are biased to their OFF state for a sufficiently long time relative to a readout period (a period during which the Amp transistors ATR are in their ON state). This decreases the temporal correlation between the 1/f noise included in the output current value when the Amp transistor ATR at the pixel P in each row is again biased to the ON state and the 1/f noise included in the output current value when, immediately beforehand, this Amp transistor ATR has been biased to the ON state.

Then, the control device 30 calculates an output value in accordance with results of n readouts of information carried by each pixel P. For example, the control device 30 may calculate, as the output value mentioned above, the arithmetic mean of output current values obtained by n sweeps. In such a manner, the control device 30 performs an operation based on a plurality of readout results with low correlations for 1/f noise and therefore may calculate an output value with reduced 1/f noise.

As described above, after resetting, information (electric charge) carried by each pixel P is read out n times, and then X-ray irradiation occurs (at a time t3 in FIG. 4). Thereby, the information (electric charge) carried by the pixel P is updated. After the X-ray irradiation, the control device 30 sweeps the above information carried by each pixel P n times by controlling the row selection unit 13. In (b) of FIG. 4, the period during which one sweep is performed after the X-ray irradiation is indicated as t4.

The n sweeps after the X-ray irradiation are the same as the n sweeps before the irradiation. Since, by the n sweeps after the X-ray irradiation, a plurality of readout results with low correlations for 1/f noise are obtained, the control device 30 calculates an output value in accordance with these readout results. Then, the control device 30 calculates a difference between the output values before and after X-ray irradiation and output the calculated value. The timing of calculation of an average value is not particularly limited and, for example, at the phase when 2n sweeps are complete, the average value before X-ray irradiation and the average value after the irradiation may each be calculated.

As described above, the solid-state imaging element 1A includes the pixel array A in which a plurality of columns of the pixels P are arranged and the row selection unit 13 that specifies a readout row of the pixel array A. The control device 30 in the solid-state imaging element 1A sweeps information carried by each of the pixels P by controlling the row selection unit 13 and outputs an output value in accordance with results of a plurality of readouts of information from each pixel P obtained by the sweeps. Thereby, an output value with reduced 1/f noise may be output by control of the row selection unit 13, without adding a new circuit or control.

### (Correction of Leakage)

In (c) of FIG. 4, changes in the output current from the pixel P in the Nth row are illustrated. When there is a current leakage in the photodiode PD, as illustrated in the drawing, the output current decreases with time during 2n readouts. In more detail, in every one readout, a gate voltage change that has a value obtained by dividing, by the capacitance of the photodiode PD, the electric charge obtained by integrating the leakage current over a readout interval, and an output current change occur.

The control device 30 may therefore calculate the average value mentioned above upon correcting an electric charge leakage that has occurred during a plurality of sweeps. For correcting, for example, information indicating the pattern of an output current fluctuation due to a leakage may be used. Examples of this information include an approximate curve indicating the pattern of an output current fluctuation. By using the approximate curve, the control device 30 performs correction to remove a value corresponding to an output change due to a leakage current from the output value calculated as described above and thus may output an output value in which the effect of the leakage current is removed.

In addition, the correction described above may be performed in accordance with a leakage amount measured in advance by using the solid-state imaging element 1A. In this case, changes in the output current value due to the leakage current in the solid-state imaging element 1A are obtained and stored in advance in the darkness condition or the like. Then, in accordance with the pattern of the stored changes in the output current value, the control device 30 performs correction to remove an amount corresponding to the output change due to the leakage current from the output value calculated as described above. Thereby, the effect of a leakage current on an output value may be removed more accurately.

### (Description of Effects)

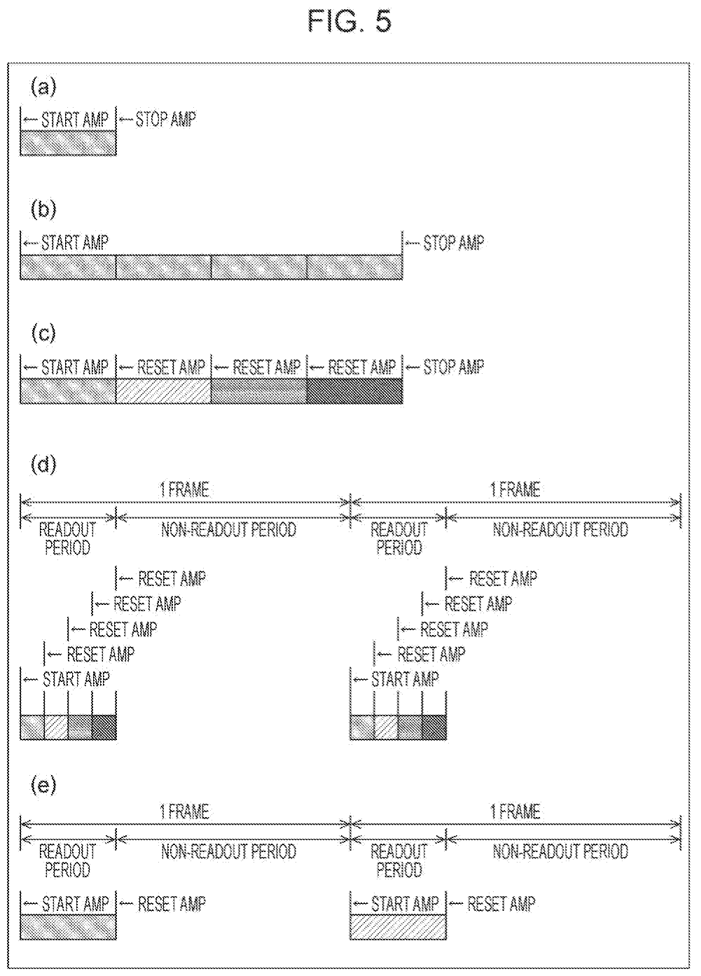

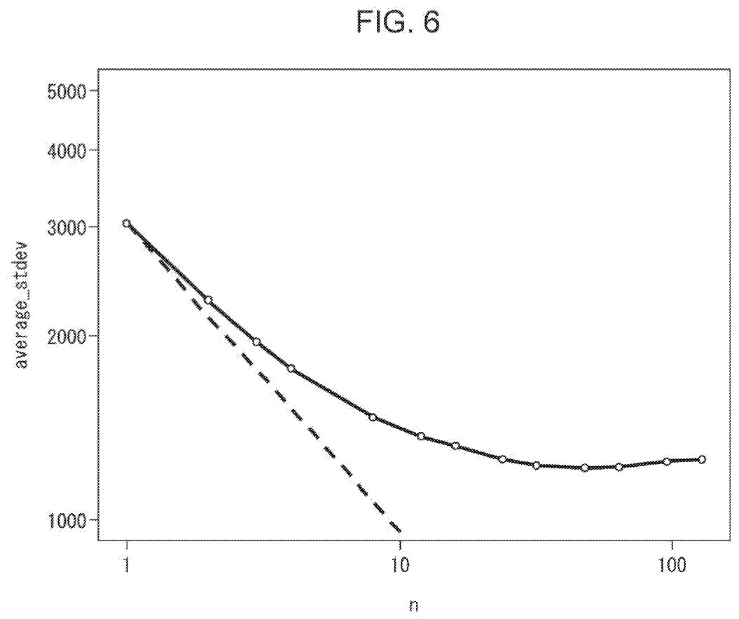

With reference to (a) to (e) of FIG. 5 and FIG. 6, operations and advantages for reducing 1/f noise of the solid-state imaging element 1A according to the present embodiment will be described. FIG. 5 is a diagram describing reduction in 1/f noise in the solid-state imaging element 1A.

In the case where the solid-state imaging element 1A is a complementary metal-oxide-semiconductor (CMOS) active pixel sensor (APS), among generated noise, 1/f noise generated in the Amp transistor ATR is greatest. The 1/f noise, which is unable to be reduced even when the measurement time is increased, is an obstacle to decreasing noise. In the case where 1/f noise is dominant, if, for example, the time between turning on and turning off the Amp transistor ATR (the length of a period during which the Amp transistor ATR is in the ON state) increases as illustrated in (a) and (b) of FIG. 5, the S/N ratio does not improve. This is because of the effect of 1/f noise that is lower-frequency, greater noise. Additionally, because of the same reason, 1/f noise is unable to be reduced even when the number of measurements increases.

As a method to reduce 1/f noise, a method of resetting the Amp transistor ATR, which is the main source of 1/f noise, is considered. This is because, for 1/f noise included in an output current value from the Amp transistor ATR, there is no correlation (or a small correlation) between before and after resetting. That is, by calculating an average value of a plurality of output current values for which there is no such correlation, noise with no correlation accumulates, which enables the effect of low-frequency noise to be reduced.

For example, as illustrated in (d) of FIG. 5, a configuration in which the operation of the Amp transistor ATR is reset a plurality of times during a readout period in one flame is considered. However, the readout period is short, for example, about 100μ sec and therefore it is assumed to be physically difficult to perform, within the readout period, reset operations the number of which is enough to sufficiently remove 1/f noise.

In addition, in the case where the solid-state imaging element 1A is applied to, for example, an imaging element using a TFT element on a glass panel, even when the bias state is cycled within the readout period in one frame as mentioned above, it is assumed that the state within the element does not sufficiently follow the control of cycling. That is, since the readout period is a short time, it is assumed that, before completion of the change in the bias state of the Amp transistor ATR, control for the next cycle is preformed, resulting in a difficulty in obtaining an effect sufficient to remove 1/f noise.

Thus, in the solid-state imaging element 1A, as illustrated in (e) of FIG. 5, the Amp transistor ATR is configured to be reset during a non-readout period in one frame. Here, one frame is a period for reading out all the rows, which is a period obtained by multiplying the time taken for reading out one row by the number of rows, for example, about 50 msec.

As described above, the Amp transistors ATR included in the pixels P in each row are in their ON state when the row is the readout target, and are otherwise in their OFF state. That is, the Amp transistor ATR becomes the ON state once during one frame, and then is reset by transitioning to the OFF state. Accordingly, by averaging the output current values read out in one to n frames, 1/f noise may be reduced and the S/N ratio may be improved.

### (Experimental Result)

FIG. 6 is a graph (solid line) illustrating the effect of reduction in 1/f noise in the solid-state imaging element 1A. Additionally, in FIG. 6, a straight line (broken line) with a slope of 1/sqrt (n) is illustrated together. In FIG. 6, the horizontal axis represents the number (n) of repeated readouts, and the vertical axis represents the magnitude of noise (1/f noise) included in an output, specifically representing a value in the number of electrons generated in the photodiode PD equivalent to the noise. As illustrated, 1/f noise in the solid-state imaging element 1A is substantially proportional to 1/sqrt (n) when the number (n) of repeated readouts is less than or equal to 10. From this result, it is found that setting the number of repeated readouts to, for example, 8 to 30 desirably enables the 1/f noise to be lowered.

### Second Embodiment

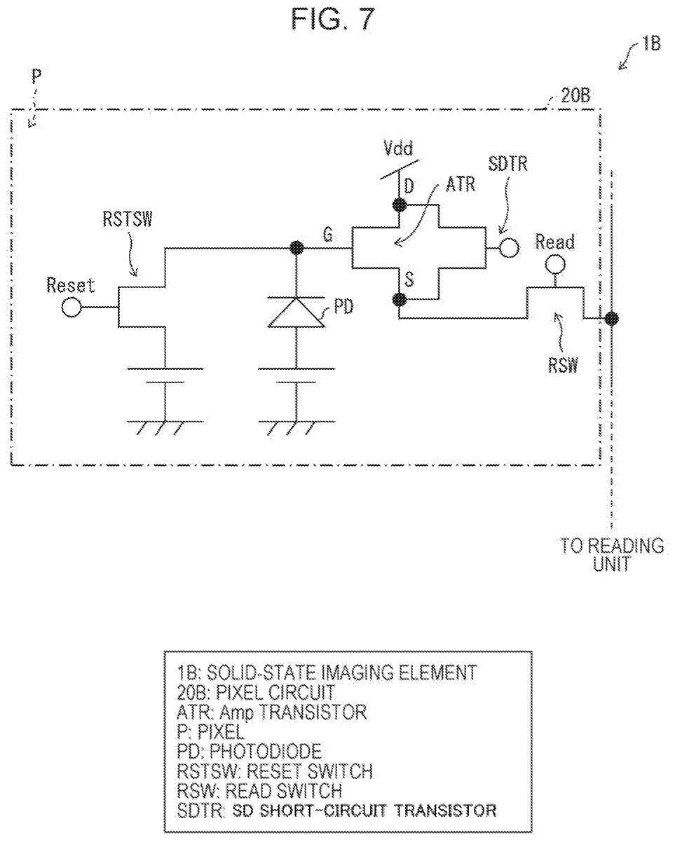

The following is a description of another embodiment of the present invention with reference to FIG. 7. Note that the configuration other than that described in the present embodiment is the same as in the first embodiment described above. Additionally, for the sake of description convenience, members having the same functions as the members illustrated in the drawings of the first embodiment described above are denoted by the same reference characters, and the description thereof is omitted.

A pixel circuit 20B of a solid-state imaging element 1B according to the present embodiment is provided with, in addition to the configuration of the pixel circuit 20A of the solid-state imaging element 1A according to the first embodiment described above, an SD short-circuit transistor SDTR that turns on and off connection between the drain electrode D and the source electrode S of the Amp transistor ATR, and differs in that, due to this configuration, the bias condition of the source potential of the Amp transistor ATR is changed.

The configuration of the pixel circuit 20B of the solid-state imaging element 1B will be described with reference to FIG. 7. FIG. 7 is a circuit diagram illustrating a configuration of the pixel circuit 20B A of the solid-state imaging element 1B.

As illustrated in FIG. 7, the pixel circuit 20B is provided with the SD short-circuit transistor SDTR that turns on and off the connection between the drain electrode D and the source electrode S of the Amp transistor ATR. As a result, in the solid-state imaging element 1B, the transistor, the Amp transistor ATR and/or the SD short-circuit transistor SDTR, enables the connection between the drain electrode D and the source electrode S to be turned on and off.

In the pixel circuit 20B in the solid-state imaging element 1B, in a readout period, the SD short-circuit transistor SDTR is turned off. As a result, in the readout period, the connection between the drain electrode D and the source electrode S is turned on by the Amp transistor ATR, and the source electrode S of the Amp transistor ATR is biased as in the first embodiment. In contrast, in a non-readout period, the Amp transistor ATR is off and the SD short-circuit transistor SDTR is turned on. Thereby, the potential difference between the drain electrode D and the source electrode S of the Amp transistor ATR is zero, such that the bias state of the Amp transistor ATR in the non-readout period is a state different from that in the readout period. Accordingly, as in the first embodiment, by changing the bias state of the source electrode S of the Amp transistor ATR, 1/f noise may be reduced.

### Third Embodiment

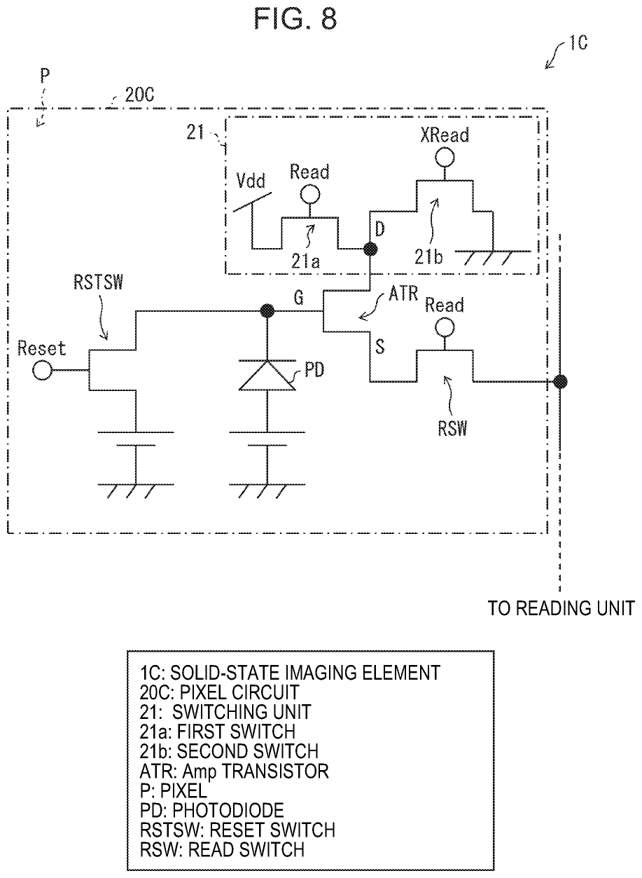

The following is a description of another embodiment of the present invention with reference to FIG. 8. Note that the configuration other than that described in the present embodiment is the same as in the first embodiment described above. Additionally, for the sake of description convenience, members having the same functions as the members illustrated in the drawings of the first embodiment described above are denoted by the same reference characters, and the description thereof is omitted.

A pixel circuit 20C of a solid-state imaging element 1C according to the present embodiment is provided with, in addition to the configuration of the pixel circuit 20A of the solid-state imaging element 1A according to the first embodiment described above, a switching unit 21 for switching the drain voltage of the Amp transistor ATR, and differs in that the bias condition of the drain potential is changed.

The configuration of the pixel circuit 20C of the solid-state imaging element 1C will be described with reference to FIG. 8. FIG. 8 is a circuit diagram illustrating a configuration of the pixel circuit 20C of the solid-state imaging element 1C.

As illustrated in FIG. 8, the switching unit 21 includes a first transistor 21a and a second transistor 21b. The first transistor 21a is a TFT having one end coupled to the drain electrode D of the Amp transistor ATR and the other end coupled to the power supply voltage Vdd. The second transistor 21b is a TFT having one end coupled to the drain electrode D of the Amp transistor ATR and the other end grounded.

In the pixel circuit 20C in the solid-state imaging element 1C, in a readout period, the Amp transistor ATR is biased as in the first embodiment. In contrast, in a non-readout period, the Amp transistor ATR is in a bias state that differs from that of the Amp transistor ATR in the pixel circuit 20A of the solid-state imaging element 1A.

Specifically, in a readout period, the control device 30 causes the first transistor 21a in the switching unit 21 to be in the ON state and causes the second transistor 21b to be in the OFF state. Thereby, the power supply voltage Vdd is applied to the drain electrode D in the Amp transistor ATR, such that a readout current amplified in accordance with a light reception voltage of the photodiode PD flows between the drain voltage D and the source voltage S to be output to the reading unit 14.

In contrast, in a non-readout period, the control device 30 performs control of a readout signal (Read) and a reversed signal (XRead) of the readout signal on the switching unit 21, thereby releasing the Amp transistor ATR from the power supply voltage Vdd to couple the Amp transistor ATR to the ground potential. That is, the control device 30 causes the first transistor 21a to be in the ON state and causes the second transistor 21b to be in the OFF state. Thereby, the potential of the drain electrode D of the Amp transistor ATR is zero such that the bias state of the Amp transistor ATR is a state different from that in the readout period.

As described above, in the solid-state imaging element 1C according to the present embodiment, when the pixel P becomes the non-readout state, the drain potential of the Amp transistor ATR included in this pixel P changes, and thereby the bias state of this Amp transistor ATR changes. Such a circuit configuration and control may cause the bias state of the Amp transistor ATR to change between the readout period and the non-readout period. Accordingly, a plurality of sweeps are performed as in the first embodiment described above to cause an output value in accordance with a plurality of readout results to be output, and thereby 1/f noise may be reduced.

### Fourth Embodiment

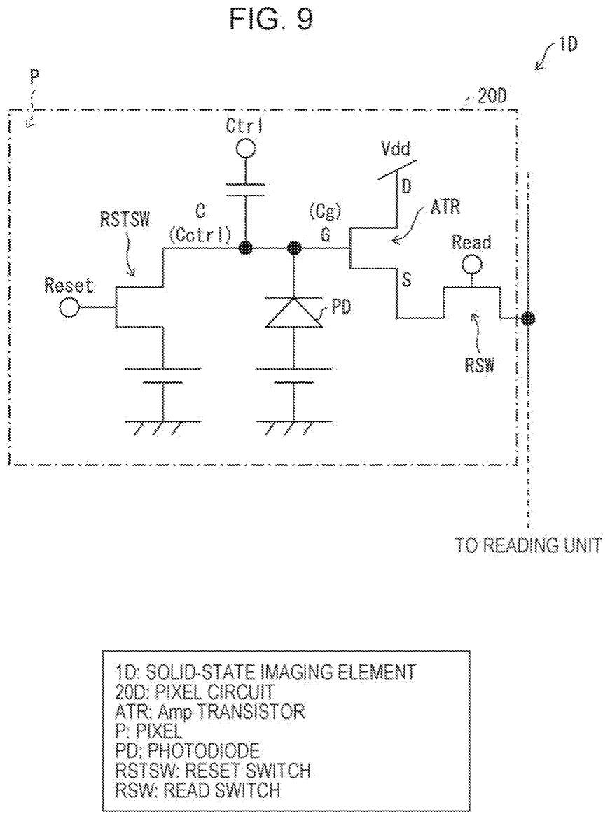

The following is a description of still another embodiment of the present invention with reference to FIG. 9. Note that, for the sake of description convenience, members having the same functions as the members illustrated in the drawings of the first embodiment described above are denoted by the same reference characters, and the description thereof is omitted.

A pixel circuit 20D of a solid-state imaging element 1D according to the present embodiment is provided with, in addition to the configuration of the solid-state imaging element 1A according to the first embodiment described above, a capacitor C is added between a signal terminal Ctrl and the gate electrode G of the Amp transistor, and differs in that the bias condition of the gate potential is changed.

The configuration of the pixel circuit 20D of the solid-state imaging element 1D will be described with reference to FIG. 9. FIG. 9 is a circuit diagram illustrating a configuration of the pixel circuit 20D of the solid-state imaging element 1D according to the present embodiment. In the pixel circuit 20D, the bias state of the Amp transistor ATR in a non-readout period differs from that in the first embodiment. Note that, in a readout period, the Amp transistor ATR is biased as in the first embodiment.

Specifically, in a non-readout period, the control device 30 sets a voltage value to be applied to the signal terminal Ctrl to a value different from that in a readout period. This may cause the voltage of the gate electrode G to change between the readout period and the non-readout period. For example, assuming that the capacitance of the added capacitor C is denoted by Cctrl and the capacitance of the gate electrode G is denoted by Cg, when the voltage of the signal terminal Ctrl is changed by Vctrl, a voltage change amount V of the gate electrode G may be calculated as expressed below.

V=Vctrl×(Cctrl/(Cctrl+Cg))

In such a manner, in the solid-state imaging element 1D according to the present embodiment, when the pixel P becomes the non-readout state, the control device 30 changes the potential of the gate electrode G of the Amp transistor ATR included in this pixel P. Thereby, in addition to a change in the bias state by opening the read switch RSW and changing the source voltage, a change in the bias state due to a potential change of the gate electrode G occurs, which may result in a larger change in the bias state of the Amp transistor ATR. Accordingly, by performing a plurality of sweeps as in the first embodiment to output an output value in accordance with a plurality of readout results, 1/f noise may further be reduced.

### Fifth Embodiment

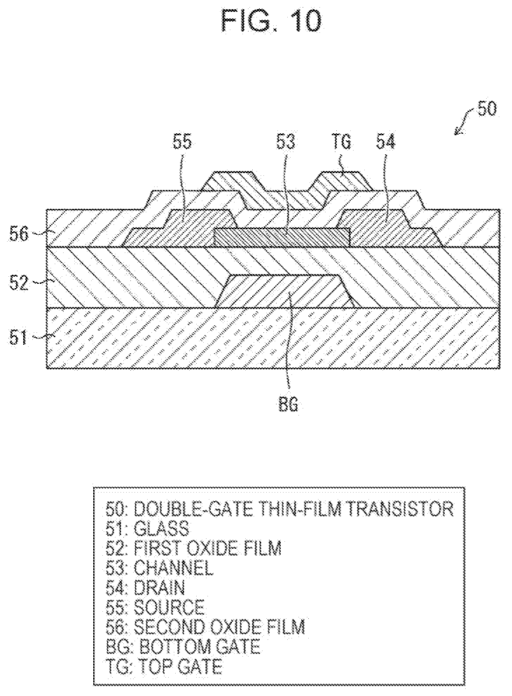

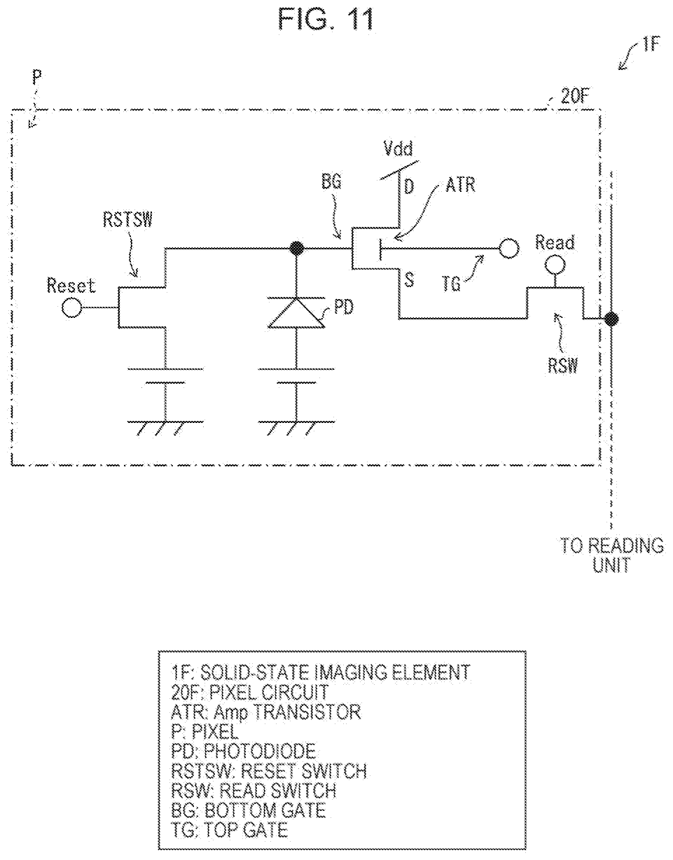

The following is a description of still another embodiment of the present invention with reference to FIG. 10 and FIG. 11. Note that, for the sake of description convenience, members having the same functions as the members illustrated in the drawings of the first embodiment described above are denoted by the same reference characters, and the description thereof is omitted.

Although, in the pixel circuit 20D of the solid-state imaging element 1D according to the fourth embodiment described above, the capacitor C is coupled to the gate electrode G to change the gate potential, the gate potential may be changed by a method different from that of the pixel circuit 20D. For example, the gate potential may be changed by using a different type of the Amp transistor ATR.

As such an Amp transistor ATR, for example, a double-gate thin film transistor may be used. FIG. 10 is a sectional view illustrating an example of a configuration of a double-gate thin-film transistor 50.

The double-gate thin-film transistor 50 includes, as illustrated in FIG. 10, glass 51, a bottom gate BG composed of molybdenum and the like, a first oxide film 52 composed of silicon nitride and the like, a channel 53 composed of InGaZnO and the like, a drain 54 composed of molybdenum and the like, a source 55 composed of molybdenum and the like, a second oxide film 56 composed of silicon oxide and the like, and a top gate TG composed of molybdenum and the like. As a result, the double-gate thin-film transistor 50 is a thin film transistor in which, in addition to the bottom gate BG in a layer below the channel 53, the top gate TG is disposed in a layer above the channel 53.

A pixel circuit 20F of the solid-state imaging element 1F according to the present embodiment includes the Amp transistor ATR using the double-gate thin-film transistor 50 in such a manner. The configuration of the pixel circuit 20F of the solid-state imaging element 1F will be described with reference to FIG. 11. FIG. 11 is a circuit diagram illustrating a configuration of the pixel circuit 20F of the solid-state imaging element 1F including the Amp transistor using the double-gate thin-film transistor 50.

In the case of using the double-gate thin-film transistor 50 as the Amp transistor ATR, as illustrated in FIG. 11, the photodiode PD is coupled to the bottom gate BG. In contrast, a voltage that differs between a readout period and a non-readout period is applied to the top gate TG. This may result in a large change in the bias state in the gate potential of the Amp transistor ATR.

### [Modifications]

In the embodiments described above, illustrative examples of the solid-state imaging elements 1A to 1F for use in capturing an X-ray image; however, targets to which a solid-state imaging element according to the present invention is applicable are not limited to these examples.

### [Summarization]

A solid-state imaging element according to a first aspect of the present invention includes a pixel array in which a plurality of columns of pixels are arranged, a row selection unit that specifies a readout row of the pixel array, and a control unit that sweeps information carried by each pixel a plurality of times by controlling the row selection unit and outputs an output value in accordance with results of a plurality of readouts of the information from each pixel obtained by the sweeping.

With the above configuration, information carried by each pixel is swept a plurality of times by controlling the row selection unit. In the sweeping, when a pixel in a row that has been the target of non-readout becomes the target of readout, the bias state of a transistor included in the pixel changes. Thus, by performing a plurality of sweeps, a plurality of readout results with no correlation for 1/f noise may be obtained. With the above configuration, since an output value in accordance with a plurality of readout results is output, an output value with reduced 1/f noise may be output by utilizing functionality of controlling row selection, with which a typical solid-state imaging element is provided.

In a solid-state imaging element according to a second aspect of the present invention, the control unit mentioned above may output, as the output value, an average value of the results of the readouts obtained by the sweeping mentioned above performed the plurality of times. Thereby, an output value with reduced 1/f noise may be output by a simple operation.

In a solid-state imaging element according to a third aspect of the present invention, the control unit mentioned above may calculate the average value mentioned above after correcting an electric charge leakage that has occurred during the sweeping performed the plurality of times. Thereby, a correct output value may be output.

In a solid-state imaging element according to a fourth aspect of the present invention, the control unit mentioned above may perform the correcting in accordance with a leakage amount measured in advance by using the solid-state imaging element. Thereby, correction with high accuracy may be performed.

A solid-state imaging element according to a fifth aspect of the present invention may be an element in which when the pixel mentioned above becomes a non-readout state, a source potential of a transistor included in the pixel changes, and thereby a bias state of the transistor changes. Thereby, an output value with reduced 1/f noise may be output by changing the bias state of the transistor, without adding a new circuit or control.

A solid-state imaging element according to a sixth aspect of the present invention may be an element in which when the pixel mentioned above becomes a non-readout state, a drain potential of a transistor included in the pixel changes, such that the bias state of the transistor changes. With such a configuration, the bias state of a transistor may be changed during each sweep, and therefore an output value with reduced 1/f noise may be output.

In a solid-state imaging element according to a seventh aspect of the present invention, when the pixel mentioned above becomes a non-readout state, the control unit mentioned above may change a potential of a gate electrode of a transistor included in the pixel. Thereby, a change in the bias state of the transistor between a readout state and a non-readout state may be emphasized. Thus, 1/f noise may further be reduced.

The present invention is not limited to the embodiments described above, various changes may be made within the scope of claims, and an embodiment obtained by appropriately combining technical measures respectively disclosed in different embodiments is also included in the technical scope of the present invention. Furthermore, by combining technical measures respectively disclosed in the embodiments, a new technical feature may be formed.

### REFERENCE SIGNS LIST

1A to 1F solid-state imaging element
13 row selection unit
30 control device (control unit)
A pixel array
ATR Amp transistor (transistor)
P pixel

1. A solid-state imaging element comprising:
a pixel array in which a plurality of columns of pixels are arranged;
a row selection unit that specifies a readout row of the pixel array; and
a control unit that sweeps information carried by each pixel a plurality of times by controlling the row selection unit and outputs an output value in accordance with results of a plurality of readouts of the information from each pixel obtained by the sweeping.

2. The solid-state imaging element according to claim 1, wherein the control unit outputs, as the output value, an average value of the results of the readouts obtained by the sweeping performed the plurality of times.

3. The solid-state imaging element according to claim 2, wherein the control unit calculates the average value after correcting an electric charge leakage that has occurred during the sweeping performed the plurality of times.

4. The solid-state imaging element according to claim 3, wherein the control unit performs the correcting in accordance with a leakage amount measured in advance by using the solid-state imaging element.

5. The solid-state imaging element according to claim 1, wherein when the pixel becomes a non-readout state, a source potential of a transistor included in the pixel changes, and thereby a bias state of the transistor changes.

6. The solid-state imaging element according to claim 1, wherein when the pixel becomes a non-readout state, a drain potential of a transistor included in the pixel changes, and thereby a bias state of the transistor changes.

7. The solid-state imaging element according to claim 1, wherein when the pixel becomes a non-readout state, the control unit changes a potential of a gate electrode of a transistor included in the pixel.
